(19) United States
(12) Patent Application Publication
(10) Pub. No.: US 2008/0272453 A1
(43) Pub. Date: Nov. 6, 2008

(54) OPTICAL DEVICE COOLING APPARATUS AND METHOD

(75) Inventor: Justin Richardson, Edinburgh (GB)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics (Research & Development) Limited, Marlow (GB)

(21) Appl. No.: 12/112,325

(22) Filed: Apr. 30, 2008

(30) Foreign Application Priority Data
May 4, 2007 (EP) 07107573.3

(51) Int. Cl. H01L 31/024; H01L 31/18

(52) U.S. Cl. 257/432; 257/433; 438/59; 257/E31.131

(57) ABSTRACT

An optical device cooling apparatus includes an image sensor array and a MEMS fan. The MEMS fan is formed integrally with the image sensor array, and cools the image sensor array.

### FIELD OF THE INVENTION

The present invention relates to an optical device cooling apparatus, and more particularly, but not exclusively, to an optical device cooling apparatus for use with a sealed optical sensing unit.

### BACKGROUND OF THE INVENTION

Complimentary metal oxide semiconductor (CMOS) image sensors allow the fabrication of digital logic on the same semiconductor substrate as a photo sensitive array.

All CMOS devices consume power and dissipate heat accordingly. A consequence of the presence of digital logic alongside an image sensor is increased heat dissipation from the semiconductor substrate. In the case of hermetically sealed camera modules incorporating a CMOS image sensor and the accompanying digital logic, the heating effect is exacerbated due to the localization of the heat dissipated. This is due in part to poor thermal conductivity between the semiconductor substrate and the packaging of the camera.

Heating of a CMOS image sensor causes deterioration in the performance of the image sensor. This is because pixels have a leakage current, also known as dark current, associated with them. The leakage current doubles with every 8° C. in temperature rise. A leakage current is indistinguishable from current generated by optically generated current, and can give rise to artefacts in images. Leakage current artefacts are most appreciable in images in which long exposures are used since the signal due to optically generated current is small compared to the signal due to leakage current.

### SUMMARY OF THE INVENTION

According to a first aspect of the present invention, an optical device cooling apparatus comprises an image sensor array and a Micro-Electro-Mechanical Systems (MEMS) cooling device, with the cooling device being arranged to cool the image sensor array.

The apparatus advantageously reduces the localized heating effect of power dissipation at the image sensor array by producing an airflow. Consequently, such an apparatus may mitigate against increase leakage current artefacts in images captured using the image sensor array.

The MEMS device may be a fan, for example. The MEMS device may be formed integrally with the image sensor array. The MEMS device may be formed from a substrate of the image sensor array.

According to a second aspect of the present invention, an optical sensor module may comprise an optical device cooling apparatus according to the first aspect. The optical sensor module may comprise a housing in which the image sensor array is housed. The housing may be sealed, and preferably hermetically sealed.

According to a third aspect of the present invention, an image capture device may comprise an optical device cooling apparatus according to the first aspect. The image capture device may comprise an optical sensor module according to the second aspect. The image capture device may comprise any one of the following: a digital still camera, a digital video camera, a mobile telephone, a web-cam and an endoscope.

### BRIEF DESCRIPTION OF THE DRAWINGS

The invention will now be described, by way of example only, with reference to the accompanying drawings, in which:

FIG. 1 is a schematic diagram of an optical device cooling apparatus according to the present invention; and

FIG. 2 is a schematic diagram of an image capture device comprising the cooling apparatus of FIG. 1.

### DETAILED DESCRIPTION OF THE PREFERRED EMBODIMENTS

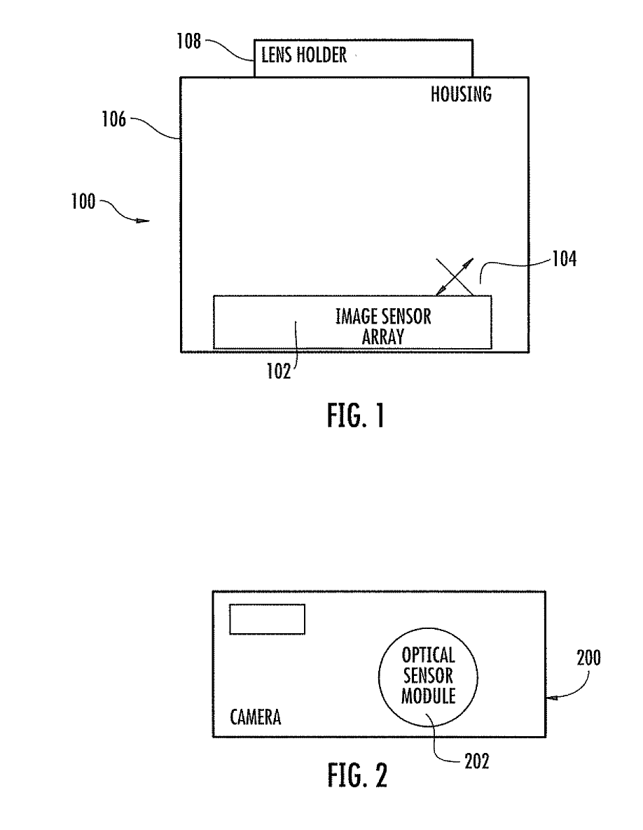

Referring now to FIG. 1, an optical sensor module 100 comprises an image sensor array 102, a MEMS fan 104, a sealed housing 106 and a lens holder 108. The sensor array 102 and fan 104 are mounted within the housing 106, and the lens holder 108 is mounted externally of the housing 106. The lens holder 108 is in line of sight of the sensor array 102.

In a preferred embodiment, the sensor array 102 and the MEMS fan 104 are integrally formed with one another. Typically, the MEMS fan 104 may be formed from a substrate 110 of the image sensor array 102.

In use, the fan draws power from a power supply, and is driven using a suitable motor as is known to a person skilled in the art. The fan 104 circulates air within the housing such that a convective flow of air is formed within the housing 106. Such a flow allows the dissipation of heat generated at the sensor array 102 through the walls of the housing 106. This reduces the heat loading on the sensor array 102. The reduction in heat loading at the sensor array 102 results in a consequential reduction in the leakage current from the pixels of the sensor array 102.

The degree of cooling of the sensor array 102 varies with the rate of flow induced within the housing by the fan 104. This will be dependent upon the size and number of blades of the fan, and also upon the speed of rotation, or oscillation, of the blades of the fan.

Referring now to FIG. 2, a camera 200 comprises an optical sensor module 202 as described above with reference to FIG. 1. It will be appreciated that although described with reference to a camera, the optical sensor module 202 may form part of any of the following: a digital still camera, a digital video camera, a mobile telephone, a web-cam, an endoscope, a bar code reader and a biosensor.

While various embodiments of the invention have been described, it will be apparent to those skilled in the art once given this disclosure that various modifications, changes, improvements and variations may be made without departing from the scope of the invention.

1-10. (canceled)

11. An optical device cooling apparatus comprising:
an image sensor array; and
a micro-electro-mechanical system (MEMS) cooling device to cool said image sensor array.

12. The optical device cooling apparatus according to claim 11 wherein said MEMS cooling device is integrally formed with said image sensor array.

13. The optical device cooling apparatus according to claim 11 wherein said MEMS cooling device comprises a fan.

14. The optical device cooling apparatus according to claim 11 wherein said image sensor array comprises a substrate; and wherein said MEMS cooling device is formed on said substrate.

15. An optical sensor module comprising:
a housing;
an image sensor array within said housing; and
a micro-electro-mechanical system (MEMS) cooling device within said housing to cool said image sensor array.

16. The optical sensor module according to claim 15 wherein said housing is sealed.

17. The optical sensor module according to claim 15 wherein said housing is hermetically sealed.

18. The optical device module according to claim 15 wherein said MEMS cooling device is integrally formed with said image sensor array.

19. The optical device module according to claim 15 wherein said MEMS cooling device comprises a fan.

20. The optical device module according to claim 15 wherein said image sensor array comprises a substrate; and wherein said MEMS cooling device is formed on said substrate.

21. An image capture device comprising:
a lens holder;
a housing adjacent said lens holder;
an image sensor array within said housing; and
a micro-electro-mechanical system (MEMS) cooling device within said housing to cool said image sensor array.

22. The image capture device according to claim 21 wherein said housing is sealed.

23. The image capture device according to claim 21 wherein said housing is hermetically sealed.

24. The image capture device according to claim 21 wherein said MEMS cooling device is integrally formed with said image sensor array.

25. The image capture device according to claim 21 wherein said MEMS cooling device comprises a fan.

26. The image capture device according to claim 21 wherein said image sensor array comprises a substrate; and wherein said MEMS cooling device is formed on said substrate.

27. The image capture device according to claim 21 wherein said lens holder, said image sensor array and said MEMS cooling device are configured so that the image capture device is at least one of a digital still camera, a digital video camera, a mobile telephone, a web-cam, an endoscope, a bar code reader and a biosensor.

28. A method for cooling an image sensor array comprising:
forming a micro-electro-mechanical system (MEMS) cooling device along with the image sensor array.

29. The method according to claim 28 wherein the MEMS cooling device is integrally formed with the image sensor array.

30. The method according to claim 28 wherein the MEMS cooling device comprises a fan.

31. The method according to claim 28 wherein the image sensor array comprises a substrate; and wherein the MEMS cooling device is formed on the substrate.
